(19) United States
(12) Patent Application Publication
(10) Pub. No.: US 2023/0420590 A1
(43) Pub. Date: Dec. 28, 2023

(54) SOLAR PANEL WITH A COMPOSITE LAMINATE

(71) Applicant: Atlas Technologies Holding B.V., Helmond (NL)

(72) Inventor: Storm POTKAMP, Arnhem (NL)

(73) Assignee: Atlas Technologies Holding B.V., Helmond (NL)

(21) Appl. No.: 18/038,109

(22) PCT Filed: Nov. 25, 2021
(86) PCT No.: PCT/EP2021/083017

§ 371 Date: May 22, 2023

(30) Foreign Application Priority Data
Nov. 25, 2020 (NL) 2026972

(51) Int. Cl. H01L 31/048; H01L 31/049; B60L 8/00; H02S 20/22

(52) U.S. Cl. CPC H01L 31/0481; H01L 31/049; B60L 8/003; H02S 20/22

(57) ABSTRACT

The invention relates to a solar panel backed by a laminate with a coefficient of thermal expansion closely matching that of soda-lime glass. Optionally, the solar panel comprises a soda-lime glass plate, a low CTE epoxy resin with a CTE of less than 50 ppm/K at room temperature, an upper layer and a lower layer each comprising two woven E-glass fibres and 33% resin weight, the E-glass fibres having an estimated Young's modulus in the x-direction and y-direction for a woven ply with x and y aligned in the two fibre directions of 26.3 GPa for each ply, and an estimated CTE of 13.3 ppm/K, having a thickness of between 0.7 and 1.4 times the thickness of the central layer, and a central layer comprising woven carbon fibres, 42% resin weight, and having an estimated Eₓₓ and E_{yy} of 62.8 GPa, as well as an estimated CTE of 1 ppm/K.

### TECHNICAL FIELD OF THE INVENTION

The invention relates to a solar panel comprising:
A glass plate,
photovoltaic devices, and
a laminate.
   The invention further relates to vehicles and building integrated photovoltaic system comprising such a solar panel

### ACKNOWLEDGEMENT

The project leading to this application has received funding from the European Union's Horizon 2020 research and innovation program under grant agreement No. 848620.

### BACKGROUND OF THE INVENTION

Solar panels are not only used as static, flat solar panels, mounted as solar cells between a glass plate and a metal mounting structure, but also as, for example, the roof and bonnet of a solar powered vehicle such as the Lightyear One, sold by Atlas Technologies, Helmond, the Netherlands. Preferably, to lower the used power per kilometer, such a car should be lightweight and, to optimize the amount of electricity generated by the solar cells, have as much solar panel area as possible. Use of the complete bonnet, roof and trunk are therefore necessary. The bonnet (as well as the roof and trunk) comprises therefore a glass plate curved in two directions, encapsulated photovoltaic devices in the form of solar cells as, for example, described in International Patent Application Publication WO2020064474A1.

Another demand is that the vehicle is safe and sufficiently robust. Especially the bonnet of a vehicle must be capable to withstand an impact with a pedestrian. The composite laminate strengthens the panel, and, as the glass is adhered to the laminate via an encapsulant such as EVA (Ethylene Vinyl Acetate) also ensures that, if the glass breaks, all shards stay together (bonded to the laminate), thus reducing possible damage to for example pedestrians.

The solar panels of a vehicle are exposed to extreme weather conditions, causing the panels to reach temperatures as high as 120° C. when on a hot windless day in full sunlight to −40° C. when in a cold, wintry night in Canada or the northern parts of e.g. Norway. This implies that a small difference in the coefficient of thermal expansion (CTE) of the glass and the composite laminate can lead to unacceptable deformation and stresses in the glass plate, and possibly results in braking or shattering of the glass. There is therefore a need for a laminate that has a CTE sufficiently matching that of glass, more specifically soda-lime glass. The invention intends to provide a solution for this problem.

### SUMMARY OF THE INVENTION

The invention provides a solar panel comprising a glass plate, photovoltaic devices and a laminate, and is characterized in that the laminate is a composite hybrid laminate comprising:
a central layer comprising one or more plies of fibres, the central layer showing an upper side and a lower side, the lower side opposite to the upper side,
an upper layer and a lower layer, each of the upper and layer lower layers comprising one or more plies of glass fibre, the upper layer in contact with the upper side of the central layer and the lower layer in contact with the lower side of the central layer, and the plies embedded in a cured polymer.

The solar panel is for example a solar panel that is suitable for being incorporated into a vehicle, for example an electric vehicle, e.g. an at least partly self-charging electrical vehicle such as an at least partly solar powered car. Alternatively or in addition the solar panel is a solar panel that is suitable for use on a building, e.g. on a building or a part thereof which is located in an environment which experiences large temperature variations.

The glass panel is for example a glass panel of soda-lime glass. Optionally, the glass panel is another type of glass.

A composite hybrid laminate typically comprises several plies of two or more materials, in a matrix of a polymer, typically a resin. The CTE of the composite laminate is governed by the CTE of the plies (the material of the plies) and that of the resin, as well as the percent by weight of these. The CTE and the strength can, in-plane, be isotropic or anisotropic. For the use of a composite as described here, CTE and stiffness in-plane should be isotropic or at least semi-isotropic. This is achieved by a proper choice of the orientation of the plies and the thickness of the plies.

Hybrid in this respect means that at least two plies comprise different fibres, here carbon fibres and glass fibres.

As is the common understanding in the art, “orientation of the plies” refers to the orientation of fibres in the respective plies.

Preferably the laminate is a symmetric, balanced laminate eliminates unwanted coupling behaviour under stress, such as bending and shear.

Symmetric in this respect means that the central layer has a mid-plane and that each ply at a distance D of the mid-plane is associated with another ply with the same orientation at a distance −D of the mid-plane. The laminate being symmetric thereby eliminates axial-flexural coupling.

Balanced in this respect means that for each ply with an (in-plane) orientation θ there is another ply with an orientation −θ.

In an embodiment, the photovoltaic cells are arranged between the glass panel and the laminate. In this embodiment, optionally the glass panel forms the outer layer of the solar panel and has a free surface which is or forms part of the outer surface of the solar panel. Optionally, in this embodiment, the laminate forms the backing structure of the solar panel, which gives the solar panel rigidity and strength.

In an embodiment, the plies of the upper layer and the lower layer are embedded in a cured polymer, more specifically a cured resin.

In an embodiment, the plies of the upper layer and the lower layer are embedded in a cured polymer, which cured polymer is a cured resin.

The soda-lime glass plate used has, in the temperature range between −40° C. and +120° C., a CTE of approximately 7.8 ppm/K.

A quasi-isotropic laminate of cured carbon fibre ply or plies, also known as Carbon Fibre Reinforced Plastic (CFRP) is known to have a low CTE, between −1 ppm/K to +1 ppm/K, so a combination of a soda-lime glass plate with this type of laminate gives a large mismatch in the CTE of laminate and glass plate.
A quasi-isotropic laminate of cured glass fibre plies, also known as Glass Fibre Reinforced Plastic (GFRP) is known to have a CTE of between +13 ppm/K to +20 ppm/K.
Therefore a CFRP cannot match the CTE of soda-lime glass plate as the CTE of the CFRP is too small, while a GFRP cannot match the CTE of a soda-lime glass plate as the CTE of the GFRP is too large.

A combination of carbon fibre plies, glass fibre plies, and resin can lead to a laminate that has a CTE sufficiently close to that of a glass plate to attach to the glass plate (for example using an encapsulant or sealant, such as EVA) and to operate in a temperature range of between −40° C. and +120° C.

It is noted that 120° C.-125° C. is in many applications the temperature at which both the resin and the encapsulant solidifies (cures, cross-links) and adhere to each other, and thus the temperature at which no stress occurs at the solar panel. Bringing the solar plate then to room temperature, or even a much lower temperature, introduces stress and thus deformation.

It is further noted that hybrid laminates comprising carbon fibre plies and glass fibre plies are known, for example from “Glass/Carbon Fibre Hybrid Composite Laminates for Structural Applications in Automotive Vehicles”, J. Zhang et al., Sustainable Automotive Technologies (2012), pp. 69-74. Here a strong, lightweight and relatively cheap hybrid laminate is sought, resulting in a laminate with equal percentage of carbon fibres and glass fibres. The paper does not describe matching the CTE of a hybrid laminate to that of glass, nor does it study the CTE of the laminate. The person skilled in the art will thus not find a solution in this publication.

In an embodiment, at least one of the plies of carbon fibre of the central layer comprises a plurality of carbon fibres that extend in a non-random direction. Optionally, in at least one of the plies of carbon fibre in the central layer, multiple carbon fibres extend in the same non-random direction. For example, in at least one of the plies of carbon fibre in the central layer, at least 50%, e.g. at least 75%, of the carbon fibres extend in the same non-random direction.

Although it is possible to manufacture a laminate from e.g. randomly oriented fibres, a much more controlled laminate results from using a more controlled orientation of the fibres.

In an embodiment, at least one of the plies of glass fibre of the upper layer comprises a plurality of glass fibres that extend in a non-random direction. Optionally, in at least one of the plies of glass fibre in the upper layer, multiple glass fibres extend in the same non-random direction. For example, in at least one of the plies of carbon glass in the upper layer, at least 50%, e.g. at least 75%, of the glass fibres extend in the same non-random direction.

Although it is possible to manufacture a laminate from e.g. randomly oriented fibres, a much more controlled laminate results from using a more controlled orientation of the fibres.

In an embodiment, at least one of the plies of glass fibre of the lower layer comprises a plurality of glass fibres that extend in a non-random direction. Optionally, in at least one of the plies of glass fibre in the lower layer, multiple glass fibres extend in the same non-random direction. For example, in at least one of the plies of carbon glass in the lower layer, at least 50%, e.g. at least 75%, of the glass fibres extend in the same non-random direction. Although it is possible to manufacture a laminate from e.g. randomly oriented fibres, a much more controlled laminate results from using a more controlled orientation of the fibres.

In an embodiment, at least one of the plies of glass fibre in the upper layer comprises a plurality of glass fibres that extend in a non-random direction. Optionally, in at least one of the plies of glass fibre in the upper layer, multiple glass fibres extend in the same non-random direction. For example, in at least one of the plies of carbon glass in the upper layer, at least 50%, e.g. at least 75%, of the glass fibres extend in the same non-random direction.

In addition, in this embodiment, at least one of the plies of glass fibre in the lower layer comprises a plurality of glass fibres that extend in a non-random direction. Optionally, in at least one of the plies of glass fibre in the lower layer, multiple glass fibres extend in the same non-random direction. For example, in at least one of the plies of carbon glass in the lower layer, at least 50%, e.g. at least 75%, of the glass fibres extend in the same non-random direction.

Although it is possible to manufacture a laminate from e.g. randomly oriented fibres, a much more controlled laminate results from using a more controlled orientation of the fibres.

In an embodiment, at least one of the plies of carbon fibre in the central layer comprises a plurality of carbon fibres that extend in a non-random direction. Optionally, in at least one of the plies of carbon fibre in the central layer, multiple carbon fibres extend in the same non-random direction. For example, in at least one of the plies of carbon fibre in the central layer, at least 50%, e.g. at least 75%, of the carbon fibres extend in the same non-random direction.

In addition, in this embodiment, at least one of the plies of glass fibre in the upper layer comprises a plurality of glass fibres that extend in a non-random direction. Optionally, in at least one of the plies of glass fibre in the upper layer, multiple glass fibres extend in the same non-random direction. For example, in at least one of the plies of carbon glass in the upper layer, at least 50%, e.g. at least 75%, of the glass fibres extend in the same non-random direction.

Alternatively or in addition, in this embodiment, at least one of the plies of glass fibre in the lower layer comprises a plurality of glass fibres that extend in a non-random direction. Optionally, in at least one of the plies of glass fibre in the lower layer, multiple glass fibres extend in the same non-random direction. For example, in at least one of the plies of carbon glass in the lower layer, at least 50%, e.g. at least 75%, of the glass fibres extend in the same non-random direction. Although it is possible to manufacture a laminate from e.g. randomly oriented fibres, a much more controlled laminate results from using a more controlled orientation of the fibres.

In an embodiment of the invention at least one of the plies comprises unidirectional fibres.

Although it is possible to manufacture a laminate from e.g. non-oriented fibres, a much more controlled laminate results from using a more controlled orientation of the fibres.

In another embodiment of the invention at least one of the plies comprises woven fibres.

Although it is possible to manufacture a laminate from e.g. non-oriented fibres, a much more controlled laminate results from using a more controlled orientation of the fibres.

In an embodiment, a ply of carbon fibres of the central layer comprises continuous carbon fibres. These continuous carbon fibres for example extend form one edge of the ply to another edge of the ply. Alternatively or in addition, the ply of carbon fibres contains carbon fibres having a length of 3 centimetres-25 centimetres, e.g. 5 centimetres-15 centimetres, and/or carbon fibres having a length of 5 centimetres or less.

In an embodiment, a ply of glass fibres of the upper layer comprises continuous glass fibres. These continuous glass fibres for example extend form one edge of the ply to another edge of the ply. Alternatively or in addition, the ply of glass fibres contains glass fibres having a length of 3 centimetres-25 centimetres, e.g. 5 centimetres-15 centimetres, and/or carbon fibres having a length of 5 centimetres or less.

In an embodiment, a ply of glass fibres of the lower layer comprises continuous glass fibres. These continuous glass fibres for example extend form one edge of the ply to another edge of the ply. Alternatively or in addition, the ply of glass fibres contains glass fibres having a length of 3 centimetres-25 centimetres, e.g. 5 centimetres-15 centimetres, and/or carbon fibres having a length of 5 centimetres or less.

In an embodiment, the central layer comprises a first central layer ply of carbon fibres, in which first central layer ply the majority of the carbon fibres, optionally all of the carbon fibres, extend in a first direction. In this embodiment, the upper layer comprises a first upper layer ply of glass fibres, in which first upper layer ply the majority of the glass fibres, optionally all of the glass fibres, extend in a second direction which is different from the first direction. In this embodiment, the lower layer comprises a first lower layer ply of glass fibres, in which first lower layer ply the majority of the glass fibres, optionally all of the glass fibres, extend in a third direction.

Optionally, the third direction is the same as the second direction. This provides the advantage that is allows to provide a balanced and/or symmetrical hybrid composite laminate.

In a variant of this embodiment, the second direction and the third direction extend at an angle of 45° relative to the first direction, and the second direction and the third direction extend at an angle of 90° relative to each other.

In an embodiment, the central layer comprises a first central layer ply of carbon fibres, in which first central layer ply the majority of the carbon fibres, optionally all of the carbon fibres, extend in a first direction. In this embodiment, the central layer further comprises a second central layer ply of carbon fibres, in which second central layer ply the majority of the carbon fibres, optionally all of the carbon fibres, extend in a second direction. The second direction can be the same as the first direction or different from the first direction.

In an embodiment, the central layer comprises a first central layer ply of carbon fibres, in which first central layer ply the majority of the carbon fibres, optionally all of the carbon fibres, extend in a first direction. In this embodiment, the upper layer comprises a first upper layer ply of glass fibres, in which first upper layer ply the majority of the glass fibres, optionally all of the glass fibres, extend in a second direction. In addition, the upper layer comprises a second upper layer ply of glass fibres, in which second upper layer ply the majority of the glass fibres, optionally all of the glass fibres, extend in a fourth direction.

In addition, in this embodiment, the lower layer comprises a first lower layer ply of glass fibres, in which first lower layer ply the majority of the glass fibres, optionally all of the glass fibres, extend in a third direction. In addition, the lower layer comprises a second lower layer ply of glass fibres, in which second lower layer ply the majority of the glass fibres, optionally all of the glass fibres, extend in a fifth direction.

In this embodiment, the second direction is the same as third direction and the fourth direction is the same as the fifth direction.

Optionally, the first direction is the same as one of the second direction and the fourth direction.

In another embodiment of the invention the resin is a low CTE epoxy with a CTE of less than 50 ppm/K at room temperature. CTE is defined as coefficient of thermal expansion.

For a laminate with a sufficient amount of resin to impregnate the plies, the laminate having a CTE close to or equal to that of (soda-lime) glass it is necessary to use a resin with a (cured) CTE of less than 50 ppm/K at room temperature.

In another embodiment of the invention the glass fibres are E-glass fibres.

E-glass fibres have a CTE close to that of soda-lime glass, the glass typically used for a solar panel. Also, E-glass fibre is relatively cheap and widely available, making it a prime choice for these applications.

In another embodiment of the invention the solar panel is a curved solar panel, more specifically a double-curved solar panel.

For many uses, such as vehicles, building integrated photovoltaic elements (BIPV elements), curved or double curved panels are preferred.

In another embodiment the photovoltaic devices are photovoltaic devices from the group of multi-junction solar cells, monocrystalline silicon solar cells, poly-crystalline silicon solar cells, GaAs solar cells, perovskite solar films, or thin film solar films

In another embodiment of the invention the solar panel comprises a glass plate is a soda-lime glass plate with a thickness of between 1.5 mm and 3.0 mm, the light sensitive devices are one or more mono- or polycrystalline semiconductor cells having a light sensitive side and a opposite side opposite to the light sensitive side, the opposite side showing at least one anode and one cathode, and a back-contact foil, the cells arranged between the glass plate and the back-contact foil, the back-contact foil arranged between the one or more cells and the composite laminate, the glass, the cells, the back-contact foil and the composite laminate attached to each other by an encapsulant.

This embodiment describes the order in which the components of the solar panel are arranged. Typically the solar cells are encapsulated in an encapsulant, such as EVA, and a back-contact foil (for example a polyamide film with a copper pattern thereon) or another type of interconnection interconnects the anodes and the cathodes of the solar cells through holes in the encapsulant. The encapsulant is then laid in the glass plate and cured. The laminate may be co-cured or co-bonded, or may be bonded after the curing of the encapsulant.

In an aspect of the invention a vehicle comprises a solar panel according to the invention.

A vehicle, such as the Lightyear One, sold by Atlas Technologies, Helmond, the Netherlands, is equipped with solar panels, more specifically a (double) curved solar bonnet, roof, and trunk. As such a vehicle must operate in environments where the temperature of the roof may drop to −40° C. (for example on a cold wintry night in the north of Norway or in Canada) or rise to +120° C. (on a hot day, parked in the sun, in Spain or California). It is noted that maximum stress and deformation occurs at the lowest temperatures, as curing (solidification) of the panel takes place at approximately +120° C., resulting in a stressless situation at that temperature

In another aspect the invention relates to a building integrated photovoltaic (BIPV) system comprising a solar panel according to the invention.

A BIPV system, being part of an architectural design, preferably offers the possibility to be a (double) curved form.

### BRIEF DESCRIPTION OF THE DRAWINGS

FIG. 1 schematically shows an embodiment of the hybrid composite laminate according to the invention,

FIG. 2 schematically shows CAE analysis of the stress in a (prior art) solar car roof using an all glass-fibre laminate, and

FIG. 3 schematically shows CAE analysis of the thermal deformation in a (prior art) solar car roof using an all glass-fibre laminate.

### DETAILED DESCRIPTION OF THE INVENTION

For example International Patent Application Publication WO2020064474A describes one of several ways to adhere solar cells to a curved glass plate using a back-contact foil and an encapsulant such as EVA. Typically the cells are encapsulated in the encapsulant. Also the back-contact foil may be enclosed by the same encapsulant, or at least glued to the encapsulant. By curing the encapsulant the glass plate, solar cells and back-contact foil are ‘glued’ to the glass plate.

To increase the strength of the glass plate the plate is best supported by a laminate. To avoid thermal deformation (which might compromise for example the aerodynamic behaviour of the vehicle) and excessive stress (which might lead to damage/breaking of the glass) the CTE of such a laminate should be close to that of the glass plate. The glass plate is typically a soda-lime glass with a CTE of approximately 7.8 ppm/K. Several alternatives for a laminate exist, such as a steel support (CTE of steel is approximately 10.8 ppm/K) or a titanium support (CTE of approximately 8.1 ppm/K). Disadvantages using steel is that steel is rather heavy when compared to a laminate, while titanium is rather expensive and heavy when compared to a laminate with comparable strength. Therefore the inventor sought to find a proper laminate.

It is noted that, as known to the skilled person, a lower weight is favorable to reduce the energy consumption per kilometer (W/km).

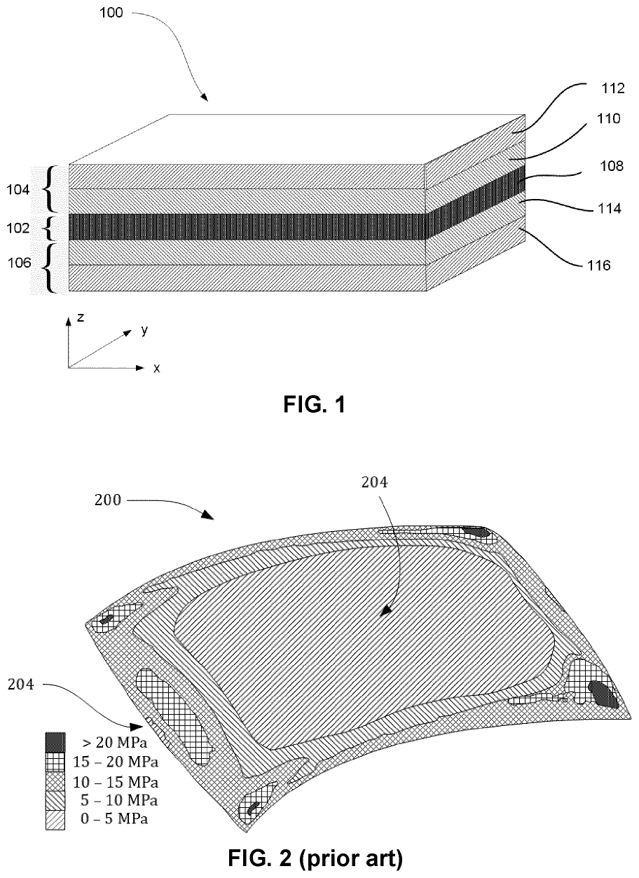

FIG. 1 schematically shows a preferred embodiment of the hybrid composite laminate according to the invention.

A central layer 102 comprises a woven ply of carbon fibres 108. Preferably the carbon ply is a pre-preg, i.e. a ply that is, before curing, already impregnated with a resin, thereby simplifying manufacturing. The laminate further comprises an upper layer 104 and a lower layer 106 surrounding the central layer. The upper layer comprises two woven plies of glass-fibre 110 and 112, preferably pre-pregs of E-glass glass-fibre, with the (woven) glass fibre plies, ply 110 and ply 112 oriented at θ=45° with respect to each other, for example ply 110 oriented at θ=0° and ply 112 oriented at θ=45°. Likewise plies 114 and 116 are part of the lower layer, with ply 114 40 oriented along ply 110 and ply 116 along ply 112.

It is noted that θ is an orientation in the x-y plane. It is further noted that for a woven ply θ=0° is equivalent to θ=90° and θ=45° is equivalent to θ=−45° (or θ=135°).

As the laminate is both symmetric and balanced, unwanted coupling behaviour, such as bending and shear, are eliminated. Proper choice of the orientation of the plies and the thickness of the plies make the CTE and the stiffness isotropic or at least semi-isotropic.

Preferably the solar panel comprises a soda-lime glass plate, a low CTE epoxy resin with a CTE of less than 50 ppm/K at room temperature, the upper layer and the lower layer comprising woven E-glass fibres and 33% resin weight, the E-glass fibres having an estimated Eₓₓ and E_{yy} (Eₓₓ Young's modulus in the x-direction and E_{yy} Young's modules in the y-direction for a woven ply with x and y aligned in the two fibre directions) of 26.3 GPa for each ply, as well as an estimated CTE of 13.3 ppm/K, and having a thickness of between 0.7 and 1.4 times the thickness of the central layer, the central layer comprising woven carbon fibres, 42% resin weight, and having an estimated Eₓₓ and E_{yy} of 62.8 GPa, as well as an estimated CTE of 1 ppm/K.

The thicknesses used in the tests and simulations described further on are:
Central layer 102 (woven carbon ply): 0.34 mm
Upper layer 104 (two woven E-glass fibre plies 110, 112): 2×0.24 mm=0.48 mm.
Lower layer 106 (two woven E-glass fibre plies 114, 116): 2×0.24 mm=0.48 mm.
Total laminate thickness: 1.3 mm.

Further tuning of thickness and amount of resin is expected to result in an even better match of the glass plate and the laminate.

It is noted that acceptable results may be achieved with non-symmetric and/or non-balanced embodiments, but a balanced and symmetric laminate is preferred.

It is worth mentioning that when fabricating the laminate, the plies can be stacked upon each other and then infused with liquid resin, or the plies can be so-called pre-pregs, already comprising the resin.

FIG. 2 schematically shows CAE analysis of the stress in a solar car roof using an all glass-fibre laminate.

First experiments and simulations of the solar roof of a solar car were performed on a (double curved) solar roof 200, the roof comprising a backing structure using a 1.7 mm glass fibre laminate and a 2.1 mm soda-lime glass plate with mono-crystalline silicon solar cells, EVA (ethylene vinyl acetate) as an encapsulant and a back-contact foil for interconnecting the cells.

The roof has a length of 1791 mm and a width of 1335 mm.

Side 202 is facing the front of the vehicle, in other words the side where the bonnet resides. Side 204 is facing upwards, i.e. is removed from the interior of the vehicle, i.e. facing upward.

Due to the bonding of the glass and solar cells and the backing structure (the laminate) at 125° C. using EVA (125° C. being the curing temperature of the EVA), and the difference in CTE between the glass and the glass fibre, a large amount of thermal residual stresses was induced in the solar panel. Current estimates for this are a maximum residual tensile stress of 20.1 MPa in the glass (design allowable is 19 MPa) at a temperature of 20° C. It is not possible to reduce these values much further while using an only glass fibre epoxy backing structure due to material limitations. A fully carbon fibre backing structure would have the same or even worse problem. An additional problem of an all carbon laminate is that the backing structure should not be electrically conductive to avoid electrical shorts between the backing structure and the back-contact foil and/or the solar cells or their connections, such as the back-contact foil.

Similar simulations were performed on the roof using the laminate of FIG. 1, with a hybrid composite comprising four woven glass fibre plies and one woven carbon fibre ply in the middle, the hybrid composite both symmetrical and balanced using the amounts and dimensions of paragraphs [0037] and [0039].

The first iteration of this design shows a residual stress of up to 3.2 MPa (was: 20.4 MPa) at a temperature of 20° C., which is well within acceptable limits, even when the temperature drops to −40° C. Further optimization, using less resin, or a different resin, can even further decrease this value.

Also, this hybrid laminate solution has a slightly lower weight than the all-glass fibre laminate with comparable cost. As known to the skilled person a lower weight is favourable to reduce the energy consumption per kilometre (W/km).

It is noted that resins with a much lower CTE do exist, but these are often filled with for example silica and thereby less suited as infusion fluid for a laminate. Other, low viscosity and low CTE resins targeted for potting electronics are available, but these are often more expensive.

It is further noted that the person skilled in the art will recognize that double curved panels show a much higher out-of-plane stiffness than non-curved or single curved panels. This results in a high thermal residual stress of the panel. For this reason, the panel shows the highest thermal residual stress at the positions where the curvature is highest (near the corners) and lowest thermal residual stress where the curvature is lowest (the middle of the roof).

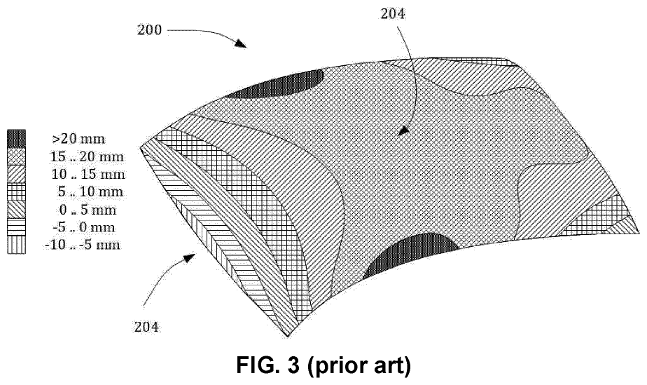

FIG. 3 schematically shows CAE analysis of the thermal deformation in a solar car roof using an all glass-fibre laminate.

First experiments and simulations were performed on a (double curved) solar roof 200 for a vehicle, the roof comprising a backing structure using a 1.7 mm glass fibre composite laminate, a 2.1 mm soda-lime glass plate with mono-crystalline silicon solar cells, EVA (ethylene vinyl acetate) as an encapsulant and a back-contact foil for interconnecting the cells. The roof has a length of 1791 mm and a width of 1335 mm.

Side 202 is facing the front of the vehicle, in other words the side where the bonnet resides. Side 204 is facing upwards, i.e. is removed from the interior of the vehicle, i.e. facing upward.

The thermal stress shown in FIG. 2, together with the geometry of the roof and the boundaries of the recess in which the roof fits, causes thermal deformation of the solar panel. The simulations and measurements for this all glass-fibre laminate lead a maximum thermal deformation of 20.7 mm at a temperature of 20° C.

It is noted that a positive thermal deformation is in a direction perpendicular to the roof surface outward of the vehicle, i.e. pointing outward, and a negative thermal deformation is in a direction perpendicular to the roof surface inward to the vehicle, i.e. pointing to the interior of the vehicle.

It is not possible to reduce these values much further while using an only glass fibre epoxy backing structure due to material limitations. A fully carbon fibre backing structure would have the same or even worse problem: the CTE of the laminate (the backing structure) would be too small. An additional problem of an all carbon laminate is that the backing structure should not be electrically conductive to avoid electrical shorts between the backing structure and the back-contact foil and/or the solar cells or their connections, such as the back-contact foil.

Similar simulations were performed on the roof using the laminate of FIG. 1, with a hybrid composite comprising four woven glass fibre plies and one woven carbon fibre ply in the middle, the hybrid composite both symmetrical and balanced using the amounts and dimensions of paragraphs [0037] and [0039].

The first iteration of this design shows a maximum thermal deformation of 3.5 mm (was: 20.7 mm) at a temperature of 20° C., which is well within acceptable limits, even when the temperature drops to −40° C. Further optimization, using less resin, or a different resin, can even further decrease this value.

It is noted that, although a vehicle roof is used to illustrate the invention, the invention is equally well applicable to solar panels used as bonnet, trunk, or any other solar panel of a vehicle. The invention is also applicable to solar panels used as or being part of Building Integrated Photovoltaic Systems (BIPS). The panel may be a flat panel, or a curved or double curved panel.

It is noted that typically the curing or crosslinking temperature of the encapsulant and the resin are close together. The curing temperature of for example EVA (Ethylene Vinyl Acetate) is between 120° C. to 140° C., depending on the curing time desired. A very similar temperature is needed for curing an epoxy resin. This implies that co-curing is possible, and that at this co-curing temperature the stress is zero, as here the materials solidify. When cooling down the solar panel (glass/encapsulant/laminate) stress builds up and thermal deformation occurs.

1. A solar panel comprising:
a glass plate,
photovoltaic devices,
a laminate,
wherein the laminate is a hybrid composite laminate comprising:
a central layer comprising one or more plies of carbon fibres, the central layer showing an upper side and a lower side, the lower side opposite to the upper side, and
an upper layer and a lower layer, each of the upper and lower layers comprising one or more plies of glass fibre, the upper layer in contact with the upper side of the central layer and the lower layer in contact with the lower side of the central layer, and the plies embedded in a cured polymer.

2. The solar panel of claim 1 in which the laminate is a balanced and symmetric laminate.

3. The solar panel of claim 1 in which at least one of the plies comprises unidirectional fibres.

4. The solar panel of claim 1 in which at least one of the plies comprises woven fibres.

5. The solar panel of claim 1 in which the resin is a low coefficient of thermal expansion epoxy with a coefficient of thermal expansion of less than 50 ppm/K at room temperature.

6. The solar panel of claim 1 in which the glass fibres are E-glass fibres, which E-glass fibres optionally have a coefficient of thermal expansion which is substantially the same as the coefficient of thermal expansion of soda-lime glass.

7. The solar panel of claim 1 in which the solar panel is a curved solar panel, more specifically a double-curved solar panel.

8. The solar panel of claim 1 in which the photovoltaic devices are photovoltaic devices from the group of multi-junction solar cells, monocrystalline silicon solar cells, poly-crystalline silicon solar cells, GaAs solar cells, perovskite solar films, or thin film solar films.

9. The solar panel of claim 1 in which the glass plate is a soda-lime glass plate with a thickness of between 1.5 mm and 3.0 mm, the light sensitive device one or more mono- or polycrystalline semiconductor cells having a light sensitive side and a side opposite to the light sensitive side showing at least one anode and one cathode, and a back-contact foil, the cells arranged between the glass and the back-contact foil, the back-contact foil arranged between the cells and the composite laminate, the glass, the cells, the back-contact foil and the composite laminate attached to each other by an encapsulant.

10. The solar panel according to claim 1,
wherein at least one of the plies of carbon fibre of the central layer comprises a plurality of carbon fibres that extend in a non-random direction, and/or
wherein at least one of the plies of glass fibre of the upper layer comprises a plurality of glass fibres that extend in a non-random direction. and/or
at least one of the plies of glass fibre of the lower layer comprises a plurality of glass fibres that extend in a non-random direction.

11. The solar panel according to claim 10,
wherein at least 50%, e.g. at least 75%, of the carbon fibres and/or the glass fibres extend in the same non-random direction.

12. The solar panel according to claim 1,
wherein:
the central layer comprises a first central layer ply of carbon fibres, in which first central layer ply the majority of the carbon fibres, optionally all of the carbon fibres, extend in a first direction,
the upper layer comprises a first upper layer ply of glass fibres, in which first upper layer ply the majority of the glass fibres, optionally all of the glass fibres, extend in a second direction, and
the upper layer further comprises a second upper layer ply of glass fibres, in which second upper layer ply the majority of the glass fibres, optionally all of the glass fibres, extend in a fourth direction, and
the lower layer comprises a first lower layer ply of glass fibres, in which first lower layer ply the majority of the glass fibres, optionally all of the glass fibres, extend in a third direction, and
the lower layer further comprises a second lower layer ply of glass fibres, in which second lower layer ply the majority of the glass fibres, optionally all of the glass fibres, extend in a fifth direction,
wherein the second direction is the same as third direction and the fourth direction is the same as the fifth direction.

13. A vehicle comprising a solar panel according to claim 1.

14. A building integrated photovoltaic system comprising a solar panel according to claim 1.
